(19) United States
(12) Patent Application Publication
(10) Pub. No.: US 2015/0286140 A1
(43) Pub. Date: Oct. 8, 2015

(54) SUBSTRATE FOR HIGH-RESOLUTION ELECTRONIC LITHOGRAPHY AND CORRESPONDING LITHOGRAPHY METHOD

(71) Applicant: COMMISSARIAT A L'ENERGIE ATOMIQUE ET AUX ENERGIES ALTERNATIVES, PARIS (FR)

(72) Inventors: Jean-Louis Imbert, Seyssinet (FR); Christophe Constancias, Sarcenas (FR)

(21) Appl. No.: 14/420,291

(22) PCT Filed: Aug. 2, 2013
(86) PCT No.: PCT/EP2013/066311

§ 371 Date: Feb. 6, 2015

(30) Foreign Application Priority Data
Aug. 8, 2012 (FR) 1257711

(51) Int. Cl. G03F 7/11; G03F 7/40; G03F 7/20

(52) U.S. Cl. CPC G03F 7/11; G03F 7/20; G03F 7/40

(57) ABSTRACT

In the field of very high-energy (50 keV or more) electron-beam lithography, a layer to be patterned by lithography is borne by a holding structure that comprises a substrate (for example made of silicon) and an intermediate layer made of a porous material of density lower than that of the same but non-porous material, this material, notably silicon or carbon nanotubes, having a low atomic number, lower than 32 and preferably lower than 20. This structure decreases the influence of backscattered electrons on high-resolution lithographic patterns.

The invention relates to electron-beam lithography.

It is known that electron beam lithography makes it possible to write or transfer very small and extremely dense patterns that cannot be written or transferred by photolithography using visible or even UV light because of diffraction effects. The resolution limit of photolithography remains of the order of the wavelength of the light used. The resolution limit of electron-beam lithography may approach 10 nanometers or even less, i.e. it must theoretically be possible to trace patterns comprising features of width and spacing of as low as 10 nanometers or even less.

Such resolutions may be useful notably for producing ultraviolet or X-ray diffractive optical elements. These diffractive optical elements may be diffraction gratings, Fresnel lenses or other elements such as what are called blazed gratings, which are regular sawtooth etched patterns intended to improve the diffraction efficiency of the etched surface. Other applications are envisionable, for example producing masks for fabricating very dense microelectronic nanostructures or direct writing of these nanostructures.

To obtain a high resolution, it is necessary to start with an electron beam of very small diameter that locally bombards the surface of a material sensitive to the energy delivered by the electrons, material that will be called electro-sensitive material below. The exposure is carried out by scanning the surface and turning on or off the beam depending on the pattern to be exposed.

The electron beam is focused on the surface using electromagnetic lenses, and these lenses produce optical aberrations that decrease as the speed of the electrons and therefore the energy of the beam increase. Furthermore, the electron beam tends to disperse (and therefore increase in size) because of the mutual repulsion that the electrons exert on one another, but this dispersion is smaller when the speed of the electrons is higher. To the author's knowledge it is not possible to produce beams of very small diameter (smaller than 5 nanometers) at energies lower than 30 keV. To obtain a beam of this diameter, required to increase resolution, it is necessary to work at higher energies. Beams of 3 nanometer diameter having Gaussian energy distributions may be produced with energies of 100 keV.

However, it is not enough to have a beam of very small diameter to obtain a very high resolution. Specifically, even if the size of the beam is optimized, two effects contribute to limit the resolution of the patterns inscribed in the electro-sensitive material. The first is dispersion of the electrons in the material in the region of impact of the beam: the electrons lose their energy over random paths once they enter into the material, and the length of these paths is proportional to the energy of the electrons. The dispersion of electrons over these random paths is one reason why feature width increases in the region of impact, this dispersion causing the sensitive material to be exposed over an area larger than that desired. The second effect is backscattering of electrons toward regions of the electro-sensitive layer corresponding to neighboring features; these backscattered electrons are either electrons not absorbed by the electro-sensitive layer and reflected back toward the latter by underlying layers, or secondary electrons freed by the primary electrons in underlying layers and backscattered toward the electro-sensitive layer; these electrons either expose zones between features, thus decreasing contrast, or add to the electrons of the direct beam that must expose neighboring features, and this may modify, as explained below, the precise definition of neighboring features.

The influence of backscattered electrons is mainly observed on the densest patterns, i.e. patterns in which exposed zones, separated by unexposed zones, are very close to one another. In an array of very closely spaced lines, not only do the intervals between exposed lines receive an undesirable dose but the exposed lines themselves, including those located a distance away of as much as a few tens of microns, may receive an excess dose related to electrons backscattered during the exposure of neighboring lines; this excess dose tends to modify (increase in the case of a positive resist) the width of the lines relative to the width that a line would have if it were far removed from any other exposed zone. In particular, lines located in the center of an array will receive an excess dose relative to lines at the edge of the array, leading to a larger line width in the center and lower line width at the edges. This results in a loss of contrast and makes it difficult to control the uniformity of the width of features over the entire area patterned.

Solutions have already been provided tending to compensate for effects due to electron backscattering. These solutions may consist in modulating dose depending on the region to be exposed (see Journal of vacuum science and technology B Vol. 11 no. 6, pp. 2741-2745, November 1993, “PROXECCO—Proximity effect correction by convolution”, EISENMANN H.; WAAS T.; HARTMANN H.); or even in correcting in advance the geometry of the patterns to be exposed (see Japanese journal of Applied Physics vol. 37, no. 12B, pp. 6774-6778, 1998, A New Approach of E-beam Proximity Effect Correction for High-resolution Applications, SIMECEK M.; ROSENBUSCH A.; OHTA T.; JINBO H.); or even in applying corrections by what is called the “Ghost” method using a mask that subtracts the error related to variations in line density (see Journal of vacuum science and technology B Vol. 17 no. 6, pp. 2860-2863, November 1999, “Proximity effect correction by the GHOST method using a scattering stencil mask”, YAMASHITA H. inter alia).

These methods are mathematically complex and imperfect. They depend on the geometry of the patterns to be produced, on the energy of the incident beam and on the nature of the materials present in the target to be exposed.

The substrate that holds the electro-sensitive layer to be subjected to the electron lithography operation participates in the production of backscattered electrons. This is the case for substrates made of silicon (frequently used for electronic devices) or of glass (frequently used to produce photolithography masks). It has therefore also been proposed to thin the substrate in the zone to be patterned by lithography, thereby partially limiting backscattering.

It has also been proposed to use, under the electro-sensitive layer, a thin layer of amorphous carbon of about one hundred nanometers in thickness (article Nanometer Patterning by Electron Beam Lithography Using an Amorphous Carbon Film as an Intermediate Layer, in Japanese Journal of Applied Physics, Vol. 30, No. 4, April 1991, pp. 890-891). The results are not satisfactory in particular for high-energy incident beams.

It is proposed according to the invention to form, between the substrate and the electro-sensitive layer, an intermediate layer made of a material that is porous and therefore at least two times lower in density than the same but non-porous material, this material having a low atomic mass, lower than 32 and preferably lower than 20. The porous layer is preferably made of porous silicon (atomic mass 14) or of porous carbon (atomic mass 6) and in the latter case of carbon nanotubes (comparable to a porous material because of its low density). Because of its low density and its low atomic mass, this porous layer decreases the production of backscattered electrons and above all scatters them over a wider area, causing less disruption of adjacent features. The density of the material, and in particular of the silicon or carbon, is at least two times lower than the density of the same but non-porous material (single-crystal silicon for example or spin-on-carbon for example); the porous layer thus has a density preferably lower than 1.5 and even lower than 1 or even 0.5. In comparison, non-porous silicon has a density of about 2.5 and non-porous amorphous carbon has a density comprised between 1.8 and 2.1. The density of the porous material is preferably comprised between 0.1 and 0.5 times the density of the non-porous material, for silicon, and may even be even lower for carbon nanotubes (the density of a layer of carbon nanotubes may be as low as 0.1 or even less, or about 20 times less than the density of non-porous carbon). The porosity is related to the presence of spaces devoid of material between zones of material, i.e. between zones containing atoms of the material in question.

The invention therefore provides a holding structure bearing a thin layer of material to be selectively processed in a high-resolution pattern, said layer furthermore being intended to receive a layer of electro-sensitive material for defining the pattern, the holding structure comprising the superposition of a substrate and of a layer of porous material as indicated in the preceding paragraph.

The expression “layer of material to be processed” is understood to mean a semiconductor or insulating or conductive layer on which it is desired to carry out localized processing in a well-defined high-resolution pattern; this processing may notably be etching of the layer or implantation of impurities into a semiconductor layer, or localized oxidation of the layer, etc.

The layer of electro-sensitive material is deposited, except for particular cases, on the layer of material to be processed; however, in the case of a process employing a liftoff operation, the layer of material to be processed will be deposited after the layer of electro-sensitive material has been exposed and developed.

The layer of electro-sensitive material may be a resist the properties of which (for example the degree of polymerization) are modified by the electron beam that bombards it; said resist is exposed to the electron beam, which is scanned over the area in the desired pattern, then the resist is developed in order to remove the exposed portions and keep the others (in the case where it is a question of a positive resist) or in contrast remove the unexposed portions and keep the exposed portions (in the case of a negative resist).

The holding structure may furthermore comprise an insulating layer, notably made of silicon oxide, serving as a buffer between the porous layer and the layer to be processed, or as a buffer between the porous layer and a superposition of layers, among which layers the layer of material to be processed and the layer of electro-sensitive material feature.

The layer of material to be processed may be made of single-crystal silicon, the processing possibly being localized implantation of dopant impurities in a pattern defined by the pattern of exposure to the electron beam. The layer of material to be processed may also be a metal or insulating or semiconductor layer notably deposited:
on the porous intermediate layer;
or on a layer of single-crystal silicon itself deposited on the porous intermediate layer.

In practice, notably in the case of fabrication of an electronic circuit on silicon, the holding structure will be formed from a first substrate covered on its front side with the porous layer; then a second substrate will be bonded against the front side of the first substrate (with or without adhesive material). The second substrate is preferably a single-crystal silicon substrate coated with a superficial insulating layer (preferably of silicon oxide) applied to the front side of the first substrate. The second substrate is then thinned (by machining or by thermal and/or mechanical fracture through a fragile buried zone for example obtained by implantation) in order to retain only one single-crystal silicon layer of thickness smaller than 100 nanometers in thickness. It is this layer that will form the layer to be processed or that will be covered, directly or indirectly, by a layer to be processed.

The low-density porous layer has a thickness that is preferably at least equal to the mean free path of electrons in the material of the layer for the energy of the exposing beam in question. For energies of about 100 keV, the mean free path is a few tens of microns in silicon or carbon and the thickness of the porous layer is preferably at least 20 microns, preferably at least 50 microns and in particular between 50 and 100 microns for these two materials.

The porous intermediate layer could be made of a compound material rather than an elementary material, provided that this compound material has an average atomic mass meeting the criteria indicated above. Alumina Al₂O₃ could be envisioned. Lithium carbide also, of particularly low average atomic mass. However, the preferred materials remain porous silicon and porous carbon in nanotube form because currently their industrial processing is easily envisioned. Atomic mass, or average atomic mass, in the case of a molecule made up of a plurality of atoms is here defined as being the sum of the atomic masses of the atoms of the molecule, divided by the number of atoms in the molecule.

Apart from a structure for holding a layer to be processed, the invention also relates to an electron lithography process, which comprises forming a holding structure comprising a substrate covered with a porous layer of a material having a density lower than half the density of the same but non-porous material and having an atomic mass lower than 20, depositing on the porous layer a layer of material to be selectively processed in a high-resolution pattern, depositing a layer of material sensitive to an electron beam, and exposing the layer of sensitive material to a high-energy electron beam in order to define the pattern in said layer of sensitive material, then an operation of processing, by implantation and/or etching, the layer of material to be selectively processed.

Other features and advantages of the invention will become apparent on reading the following detailed description that is given with reference to the appended drawings, in which:

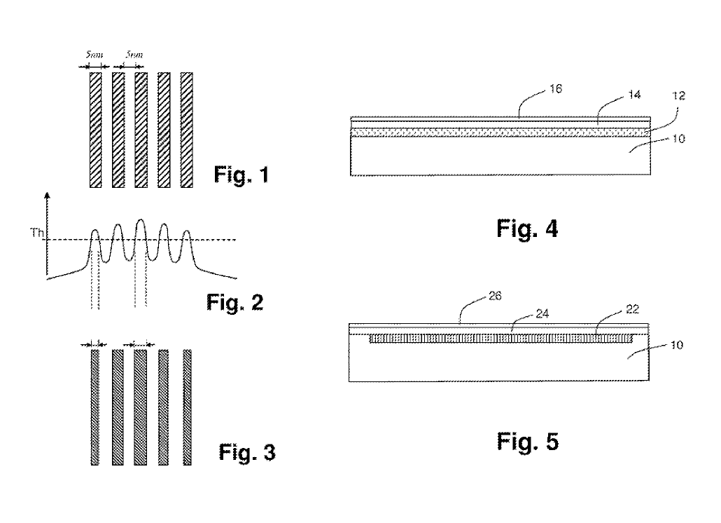

FIG. 1 schematically shows a dense pattern made up of an array of lines to be inscribed in a sensitive layer;

FIG. 2 shows a curve showing the profile of energy deposited by the electrons during exposure of the array;

FIG. 3 shows the effect that results therefrom in the pattern actually inscribed in the sensitive layer;

FIG. 4 shows a holding structure according to the invention in a simple case, with an intermediate layer of porous silicon;

FIG. 5 shows a holding structure according to the invention in a simple case, with an intermediate layer of carbon nanotubes;

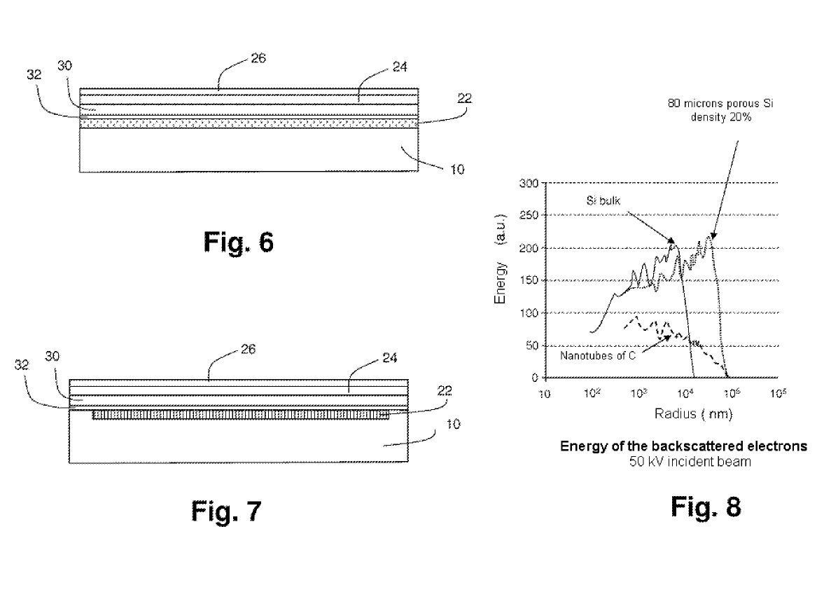

FIG. 6 shows a holding structure in the case of fabrication of the electronic circuit using a thin layer of single-crystal silicon;

FIG. 7 shows an analogous structure with porous carbon; and

FIG. 8 shows the distribution of energy of backscattered electrons about a point of impact of the electron beam as a function of distance to the point of impact.

FIG. 1 shows a regular dense pattern of lines that it is desired to inscribe in a layer sensitive to electrons, or electro-sensitive layer, that is deposited on a substrate. The pattern comprises, by way of example, lines of 5 nanometers width spaced apart by intervals of 5 nanometers.

The electron beam that is used to expose the sensitive layer has a diameter smaller than 5 nanometers, and for this purpose it has a very high energy, preferably of 30 to 100 keV or more; because of this high energy, electrons are backscattered in the substrate that bears the sensitive layer, and these electrons may expose the sensitive layer outside of the region of impact of the beam, either between the lines to be exposed or on lines neighboring the place of impact of the beam. From the backscattering of electrons toward the intervals between the lines, there results a risk of partial exposure of the sensitive layer there where it should not be exposed. From the backscattering of electrons toward neighboring lines, there results a risk of overexposure of the neighboring lines that receive (or have received beforehand or will receive subsequently) an intentional impact of the high-energy electron beam during the scanning of the surface by the beam.

FIG. 2 schematically illustrates, in arbitrary units, the energy received by the sensitive layer level with each of the various lines of the array, in a configuration in which the energy originating from backscattered electrons is taken into account. A line at the center of the array receives more energy (for a given direct-beam energy) than the lines located at the edge of the array. Likewise, a line in a dense array receives more energy than a line in a less dense array.

If the behavior of the sensitive layer is simplified, the sensitive layer may be considered to be exposed above a threshold of received energy and not to be exposed below this threshold. The threshold is represented by a line of level Th in the curve in FIG. 2. As the energy distribution in each line is Gaussian in shape, it may be seen that the width of the zone actually exposed depends on the overall energy received, and that this width therefore varies depending on whether the exposed line is in a densely patterned region (with the influence of backscattered electrons) or in a less densely patterned region (without the influence of backscattered electrons). The influence of backscattered electrons may extend over several tens of microns, which means, for lines having a pitch of 10 nanometers, that this influence may extend over several hundred neighboring lines, so that a given line receives electrons backscattered by the exposure of several hundred other lines. Even if the amount of electrons received in this way is low each time, the cumulative amount is large.

This results, as shown in FIG. 3, in a pattern of actually exposed lines that exhibit a nonuniformity in line width, the nonuniformity being related in particular to the density of the inscribed patterns. Lines at the center of a dense array receive a higher dose of electrons than lines on the edges of the array or than lines that are isolated or that form part of a less dense array.

These effects may be modeled using equations such as the Bethe equation that give the energy lost (−dE) by a beam of electrons per elementary distance (dS) traveled through a layer of material; this energy loss is reflected in various processes such as the emission of secondary electrons, braking radiation (also called “bremsstrahlung emission”) and plasmon excitation:

$$- \frac{d E}{d S} = \frac{4 π NZ}{{( 4 {πɛ}_{0} )}^{2}} \cdot \frac{{e}^{4}}{2 {E}_{0}} {ln ( \frac{4 {E}_{0}}{I} )}^{1 / 2}$$

εₒ is the permittivity of vacuum;

e is the charge on an electron;

N is the number of atoms per unit volume; this number is related to the density of the material, which is larger if N is larger and smaller if N is smaller;

Z is the atomic number of the material;

E₀ is the energy of the incident electrons, which is typically from 50 keV to 150 keV for beams of 2 to 4 nanometers in diameter;

I is the average ionization energy of the material in which the electrons propagate; it depends on atomic number and it is defined empirically; a value sometimes given in the literature, in electron volts, is I=(9.76+58.8×Z^{1.19}) for Z higher than or equal to 13, or sometimes the simplified expression I=11.5×Z.

From this equation the information is drawn that the mean free path S_{diff} varies proportionally to the square of the energy E₀ of the incident beam. The mean free path is the distance traveled leading to an electron energy loss of 50%.

The following table gives an estimation of mean free path S_{diff} as a function of incident energy E₀ for silicon:

| Energy E₀ (keV) | 5 | 50 | 95 | 150 |
|---|---|---|---|---|
| S_{diff} (μm) | 0.13 | 8 | 22 | 45 |

Furthermore, from the Bethe equation, the conclusion is drawn that the parasitic dose of backscattered electrons, which will pointlessly expose the electro-sensitive layer, is substantially proportional to density (via N) and atomic number, and substantially inversely proportional to the incident energy E₀.

According to the invention, the electro-sensitive layer to be exposed by lithography is not deposited directly on a silicon substrate or a glass substrate, but is deposited on a porous intermediate layer, i.e. a layer of material of low density, of low atomic mass (lower than 32 and preferably lower than 20). The preferred materials according to the invention are porous silicon (atomic number 14) or carbon in the form of nanotubes (atomic number 6) comparable to a porous layer because of its very low density. The porosity of this layer decreases the number N, correspondingly decreasing energy loss and therefore the number of backscattered electrons. The density of the intermediate layer is at least two times lower than the density of the same but non-porous material (amorphous material if it is a question of carbon).

Preferably, the thickness of this intermediate layer is larger than or equal to the mean free path S_{diff} for the exposure energy E₀ envisioned, for example larger than 20 microns for about one hundred keV.

FIG. 4 shows a holding structure according to the invention in the simplest case: the holding structure comprises the superposition of a substrate 10 of silicon or glass, and of a layer 12 of porous silicon.

On this structure is deposited in this case a layer 14 of material to be processed (implanted or etched or oxidized for example). This layer may for example be made of single-crystal silicon, or of metal, of chromium for example. It is a very thin layer (less than one hundred nanometers in thickness) that itself engenders no or very little backscattering of electrons due to its very small thickness.

Lastly, on the layer 14 is deposited a layer 16 made of material sensitive to an electron beam, for example a PMMA (polymethyl methacrylate) resist.

The porous silicon layer preferably has a density comprised between 10% and 50% of the normal density of bulk single-crystal silicon (bulk silicon); it has a thickness of at least 50 microns, and preferably of about 80 microns. These values are very suitable for electron beam energies of about 100 keV.

The formation of the porous silicon is a low-cost operation. It may consist in carrying out an electrochemical anodization from the single-crystal silicon surface of the substrate. The substrate is placed between two electrodes in an HF/ethanol bath. A potential difference is applied between the electrodes. The F⁻ fluorine ions of the bath are attracted toward the substrate and react with the silicon to form pores. Once the first pores have been formed, the attack of the silicon by HF takes place preferentially at the bottom of the pores and leads to the formation of porous silicon.

The porous silicon may optionally be doped.

In another embodiment schematically shown in FIG. 5, the intermediate layer of low density formed on the substrate 10 is a layer of carbon nanotubes 22. Its porosity may be very high since it is for example possible to deposit nanotubes of 5 nanometer diameter and 1 nanometer wall thickness in a number possibly of about 5×10¹¹ per cm². This gives a density that is from 3 to 4% of the density of bulk carbon (amorphous spin-on-carbon). This density may thus reach 0.1 and even less. It is also possible to use multiwall nanotubes the base diameter of which is rather about 100 nanometers.

For low-density carbon as for low-density silicon, the thickness will preferably be larger than the mean free path of electrons for the energy of the incident electron beam. Preferably, the thickness of the layer of carbon nanotubes is at least 50 microns and preferably about 80 microns.

It is desirable to make provision for the layer of carbon nanotubes to be confined laterally, because of its fragility, so that it can then withstand the deposition of other layers or further processing. The layer 12 may for this purpose be deposited in one or more compartments. The compartments may be formed by indents in the substrate 10, or indeed by the surface of the substrate encircled by a silicon frame added to the substrate.

On the layer 12 held in place in this way, a layer 24 of material to be processed and a layer 26 of electro-sensitive material are deposited. It is also possible to deposit, before the layer of material to be processed and the layer of electro-sensitive material, a protective layer that may be made of carbon, or silicon nitride or oxide, or graphene (the latter being a monolayer of crystalline carbon).

In one embodiment intended for microelectronic applications, provision will possibly be made for the holding structure to take the form shown in FIG. 6. Said structure is fabricated by bonding a second substrate against a first substrate. The first substrate 10 is for example a silicon substrate; it is covered on its front side with the porous layer 22 (formed for example by electrochemical anodization of the substrate). Then a second substrate 30, made of single-crystal silicon or covered with a single-crystal silicon layer is bonded against the porous layer. A silicon oxide layer 32 is preferably formed on the second substrate before the bonding operation.

The bonding takes place preferably without adhesive material (i.e. it is direct bonding (also called molecular adherence bonding)) between two very flat surfaces of very low roughness. Most of the thickness of the second substrate is removed until only a very thin layer of single-crystal silicon of a few tens of nanometers remains. Because of this small thickness, this layer does not engender significant backscattering of electrons during the impact of the high-energy beam. This layer of silicon will be the layer of material to be processed or will be covered with a thin layer 24 of material to be processed, itself covered with the electro-sensitive material 26.

FIG. 7 schematically shows an analogous structure fabricated in the same way in the case where the porous layer 22 is a layer of carbon nanotubes confined in indents in the surface of the substrate 10.

It has been possible to observe, via software for simulating electron paths such as Sceleton or Casino (commonly used in electron lithography), the behavior of backscattered electrons in this case. It is observed that at low energies (about 5 keV), the addition of a thin carbon layer greatly decreases the backscattered energy; however at high energy (of about 50 keV or more) such a layer has no effect for a thickness larger than the electron mean free path (typically longer than 8 microns at 50 keV).

However, at high energies, a layer of porous silicon or porous carbon made of nanotubes produces an effect of redistribution of the zones of impact of the backscattered electrons. More precisely, the backscattered electrons are dispersed over a much larger radius than is the case when the electro-sensitive layer is deposited directly on or very close to the bulk silicon or glass substrate. Thus, the impact of the backscattered electrons on the other elements of the pattern to be exposed is considerably smaller if the thickness of the porous layer is large enough (in practice: at least 20 microns for energies of more than 50 keV).

FIG. 8 shows, in arbitrary units, the energy of backscattered electrons as a function of distance relative to the point of impact of the beam (expressed in nanometers):
in the case where the holding structure is a simple bulk silicon substrate (Sibulk, solid line);
in the case where the holding structure is made of bulk silicon covered with an 80 micron-thick intermediate layer of porous silicon of density five times lower: dotted line;
and in the case where the holding structure is made of bulk silicon covered with an approximately 80 micron-thick low-density layer of carbon nanotubes (its density is at least five times lower than the density of bulk carbon): dashed line.

With silicon, the backscattered energies may be of the same order as with bulk silicon, but these energies are dispersed over a radius that may be ten times larger than for bulk silicon, thereby very significantly decreasing the impact on the overall pattern to be exposed.

The distance in question in FIG. 8 is the distance between the point of impact of the incident beam and the point where the backscattered electrons reach the electro-sensitive layer. Therefore the abscissa of the curves is a radius in nanometers representing this distance and the ordinate of the curves is, in arbitrary units, the energy of the electrons reaching the electro-sensitive layer at this distance.

Lastly, it will be noted that it is also possible to make provision for the substrate to have a greatly thinned thickness in the zone to be exposed, so that the substrate portion liable to produce disadvantageous backscattered electrons has a thickness that is much smaller than that of the rest of the substrate. The high-energy electron beam then purely and simply passes through the material of the substrate covered by the porous layer, while engendering minimal lateral scattering.

1. A holding structure for holding a layer of material to be selectively processed in a high-resolution pattern, the structure furthermore being adapted to receive an electro-sensitive masking layer for defining the pattern, wherein the holding structure comprises the superposition of a substrate, and of an intermediate layer made of a porous material of density at least two times lower than that of the same but non-porous material, this material having a low atomic mass, lower than 32.

2. The holding structure as claimed in claim 1, wherein the atomic mass of the material is lower than 20.

3. The holding structure as claimed in claim 2, wherein the density is comprised between 0.1 and 0.5 times the density of the non-porous material.

4. The holding structure as claimed in claim 1, wherein the porous layer is made of porous silicon or of carbon nanotubes.

5. The holding structure as claimed in claim 4, wherein the thickness of the intermediate layer is at least 50 microns.

6. The holding structure as claimed in claim 1, wherein the layer of material to be processed is a layer of single-crystal silicon and wherein the holding structure comprises an insulating layer on the porous intermediate layer, the single-crystal silicon layer being formed on the insulating layer.

7. The holding structure as claimed in claim 1, wherein the layer of material to be processed is a layer of a conductive, insulating or semiconductor material deposited on a single-crystal silicon layer, and wherein the holding structure comprises an insulating layer on the porous intermediate layer, the single-crystal silicon layer being formed on the insulating layer.

8. The holding structure as claimed in claim 6, wherein the holding structure is formed by a first substrate covered on its front side with the porous layer, and a second substrate bonded against the first, the second substrate being made of single-crystal silicon coated with the insulating layer and being thinned to a thickness smaller than or equal to 100 nanometers.

9. An electron lithography process, comprising: forming a holding structure comprising a substrate covered with a porous layer of a material having a density lower than half the density of the same but non-porous material and having an atomic number lower than 20, depositing on the porous layer a thin layer of material to be selectively processed in a high-resolution pattern, depositing a layer of material sensitive to an electron beam, and exposing the layer of sensitive material to a high-energy electron beam in order to define the pattern in said layer of sensitive material, then an operation of processing, by implantation and/or etching, the layer of material to be selectively processed.

10. The electron lithography process as claimed in claim 9, wherein the material of the porous layer is silicon or carbon nanotubes.

11. The holding structure as claimed in claim 2, wherein the porous layer is made of porous silicon or of carbon nanotubes.

12. The holding structure as claimed in claim 3, wherein the porous layer is made of porous silicon or of carbon nanotubes.

13. The holding structure as claimed in claim 2, wherein the layer of material to be processed is a layer of single-crystal silicon and wherein the holding structure comprises an insulating layer on the porous intermediate layer, the single-crystal silicon layer being formed on the insulating layer.

14. The holding structure as claimed in claim 2, wherein the layer of material to be processed is a layer of a conductive, insulating or semiconductor material deposited on a single-crystal silicon layer, and wherein the holding structure comprises an insulating layer on the porous intermediate layer, the single-crystal silicon layer being formed on the insulating layer.

15. The holding structure as claimed in claim 13, wherein the holding structure is formed by a first substrate covered on its front side with the porous layer, and a second substrate bonded against the first, the second substrate being made of single-crystal silicon coated with the insulating layer and being thinned to a thickness smaller than or equal to 100 nanometers.

16. The holding structure as claimed in claim 3, wherein the layer of material to be processed is a layer of single-crystal silicon and wherein the holding structure comprises an insulating layer on the porous intermediate layer, the single-crystal silicon layer being formed on the insulating layer.

17. The holding structure as claimed in claim 3, wherein the layer of material to be processed is a layer of a conductive, insulating or semiconductor material deposited on a single-crystal silicon layer, and wherein the holding structure comprises an insulating layer on the porous intermediate layer, the single-crystal silicon layer being formed on the insulating layer.

18. The holding structure as claimed in claim 16, wherein the holding structure is formed by a first substrate covered on its front side with the porous layer, and a second substrate bonded against the first, the second substrate being made of single-crystal silicon coated with the insulating layer and being thinned to a thickness smaller than or equal to 100 nanometers.
